(19) United States
(12) Patent Application Publication
(10) Pub. No.: US 2013/0134470 A1
(43) Pub. Date: May 30, 2013

(54) LIGHT EMITTING DIODE PACKAGE MODULE

(71) Applicant: Sang Hyun SHIN, Gyunggi-do (KR)

(72) Inventor: Sang Hyun SHIN, Gyunggi-do (KR)

(73) Assignee: SAMSUNG ELECTRO-MECHANICS CO., LTD., Gyunggi-do (KR)

(21) Appl. No.: 13/539,017

(22) Filed: Jun. 29, 2012

(30) Foreign Application Priority Data
Nov. 28, 2011 (KR) 10-2011-0125242

(51) Int. Cl. H01L 33/62; H01L 33/44

(52) U.S. Cl. 257/99; 257/79; 257/E33.066; 257/E33.055

(57) ABSTRACT

Disclosed herein is a light emitting diode package module, including: a substrate; a light emitting diode package formed on the substrate; an instrument member formed below the substrate; and a magnetic body formed on the substrate, the light emitting diode package, or the instrument member.

### CROSS REFERENCE TO RELATED APPLICATION

This application claims the benefit of Korean Patent Application No. 10-2011-0125242, filed on Nov. 28, 2011, entitled “Light Emitting Diode Package Module”, which is hereby incorporated by reference in its entirety into this application.

### BACKGROUND OF THE INVENTION

1. Technical Field

The present invention relates to a light emitting diode package module.

2. Description of the Related Art

The application field of light emitting diodes having various structures includes an example disclosed in Document 1 and extends not only to backlights of liquid crystal display (LCD) televisions but also to illuminating apparatuses.

Illumination is classified as indoor illumination and outdoor illumination; unlike indoor illumination, a voltage or current to be applied particularly for outdoor illumination is large, and also, a high power package on the order of 1 W or greater is used as a light emitting diode (LED) package.

A LED emits light and heat when being driven, unlike a typical lamp; light is emitted at about 20% to about 30% of the total emissions of the LED, and heat is emitted in about 70% to about 80% of the total emissions of the LED.

In particular, when driving a LED, the generated heat is to be dissipated quickly so as to increase a light efficiency. In order to effectively transfer the generated heat, a metal circuit board is typically used.

Meanwhile, as the application field of the LED is diversified as described above, research is being conducted into various members such as a heat dissipation plate to be added to a light emitting diode package and into methods of facilitating the assembly of the members.
[Document 1] KR 10-0780196 B 2007.11.21

### SUMMARY OF THE INVENTION

The present invention has been made in an effort to provide a light emitting diode package and a light emitting diode package module for facilitating the assembly of elements to be added to the light emitting diode package.

According to a first preferred embodiment of the present invention, there is provided a light emitting diode package module, including: a substrate; a light emitting diode package formed on the substrate; an instrument member formed below the substrate; and a magnetic body formed on the substrate, the light emitting diode package, or the instrument member.

When the magnetic body is formed on the substrate, the light emitting diode package and the instrument member may each further include a metal layer that is formed on an upper surface or a lower surface of the light emitting diode package and the instrument member and is formed of a material that reacts with the magnetic body.

When the magnetic body is formed on the substrate, the light emitting diode package and the instrument member may each be formed of a metal that reacts with the magnetic body.

When the magnetic body is formed on a substrate surface of the light emitting diode package, the substrate and the instrument member may each further include a metal layer that is formed on an upper surface or a lower surface of the substrate and the instrument member and is formed of a material that reacts with the magnetic body.

When the magnetic body is formed on a substrate surface of the light emitting diode package, the substrate and the instrument member may be each formed of a metal which reacts with the magnetic body.

When the magnetic body is formed on a substrate surface of the instrument member, the substrate and the light emitting diode package may each further include a metal layer that is formed on an upper surface or a lower surface of the substrate and the light emitting diode package and is formed of a material that reacts with the magnetic body.

When the magnetic body is formed on a substrate surface of the instrument member, the substrate and the light emitting diode package may be each formed of a metal which reacts with the magnetic body.

The instrument member may be a chassis or a heat dissipation plate.

The substrate may be a circuit driving board.

A plurality of the magnetic bodies may be formed to be separated from one another on the same plane.

When the plurality of magnetic bodies include N-pole magnetic bodies and S-pole magnetic bodies, the N-pole magnetic bodies and the S-pole magnetic bodies may be alternately arranged.

According to a second preferred embodiment of the present invention, there is provided a light emitting diode package module, including: a substrate; a light emitting diode package formed on the substrate; an instrument member formed below the substrate; and a magnetic body formed on each of the substrate, the light emitting diode package, and the instrument member.

A plurality of magnetic bodies may be formed to be separated from one another on the same plane of each of the substrate, the light emitting diode package, and the instrument member.

When the plurality of magnetic bodies include N-pole magnetic bodies and S-pole magnetic bodies, the N-pole magnetic bodies and the S-pole magnetic bodies may be alternately arranged on the same plane of each of the substrate, the light emitting diode package, and the instrument member.

When the plurality of magnetic bodies include N-pole magnetic bodies and S-pole magnetic bodies, the N-pole magnetic bodies and the S-pole magnetic bodies may be alternately arranged on the regions each corresponding to the substrate, the light emitting diode package, and the instrument member.

### BRIEF DESCRIPTION OF THE DRAWINGS

FIG. 1 is a detailed view of a structure of a light emitting diode package module according to a first embodiment of the present invention;

FIG. 2 is a detailed view of a structure of a light emitting diode package module according to a second embodiment of the present invention;

FIG. 3 is a detailed view of a structure of a light emitting diode package module according to a third embodiment of the present invention; and

FIG. 4 is a detailed view of a structure of a light emitting diode package module according to a fourth embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

### Light Emitting Diode Package Module

### First Embodiment

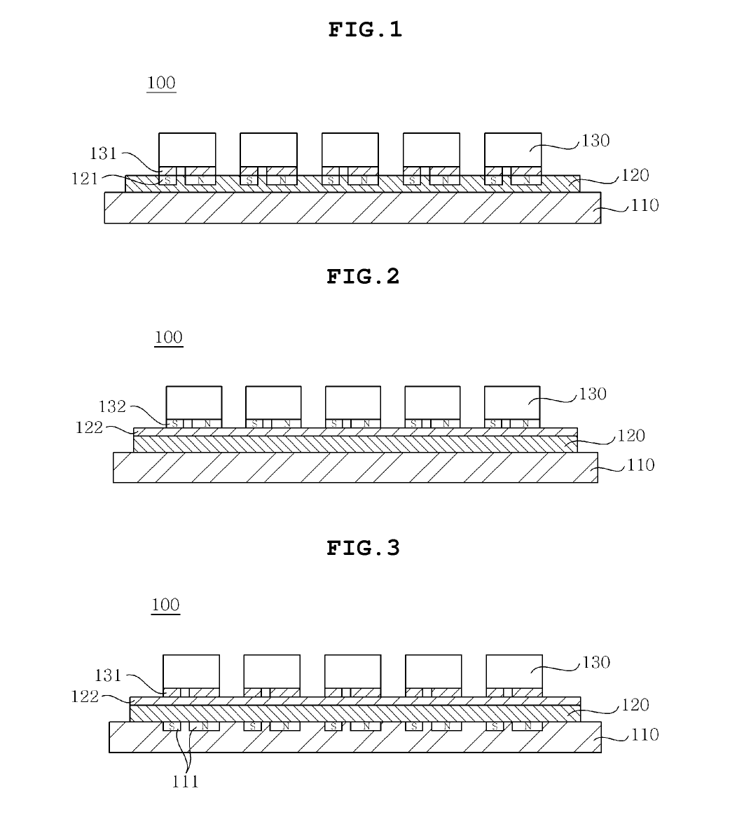

FIG. 1 is a detailed view of a structure of a light emitting diode package module according to a first embodiment of the present invention.

As illustrated in FIG. 1, a light emitting diode package module 100 may include a substrate 120, a light emitting diode package 130 formed on the substrate 120, an instrument member 110 formed below the substrate 120, and magnetic bodies 111, 121, and 132 formed on the substrate 120, the light emitting diode package 130, or the instrument member 110.

As illustrated in FIG. 1, when the magnetic body 121 is formed on the substrate 120, the light emitting diode package 130 and the instrument member 110 each may further include a metal layer 131 that is formed on an upper surface or a lower surface of the light emitting diode package 130 and the instrument member 110 and is formed of a material that reacts with the magnetic body 121.

A metal layer formed in the instrument member 110 is omitted in FIG. 1 for convenience of description. However, a metal layer may be formed on the upper surface of the lower surface of the instrument member 110.

Here, as illustrated in FIG. 1, the magnetic body 121 may be formed on a surface of the substrate 120 that contacts the light emitting diode package 130, but is not limited thereto; the magnetic body 121 may be formed at any position as long as a bonding efficiency of elements of the light emitting diode package module 100 may be increased.

For example, a metal layer may be formed in the form of a coating on the entire surface of the outermost layers of the light emitting diode package 130 and the instrument body 110. This also applies to an embodiment which is to be described below, in which a metal layer is formed on the substrate 120. Here, when electrically connecting the elements of the light emitting diode package module 100, details in terms of preventing a short circuit needs to be considered.

In addition, the metal layer 131 may be formed of iron or nickel which reacts with the magnetic body 121, but is not limited thereto. For example, the metal layer 131 may be formed as a coating layer by using a plating process, but is not limited thereto.

Meanwhile, when the magnetic body 121 is formed on the substrate 120, the light emitting diode package 130 and the instrument member 110 may each be formed of a metal that reacts with the magnetic body 121.

For example, the light emitting diode package 130 and the instrument member 110 may be formed by using materials including iron or nickel which reacts with the magnetic body 121.

Accordingly, an additional metal layer is not necessary on the light emitting diode package 130 and the instrument member 110, but the embodiment of the present invention is not limited thereto. For example, an additional metal layer may be formed on the light emitting diode package 130 and the instrument member 110 so as to further improve an attractive force between the light emitting diode package 130 and the instrument member 110 and the magnetic body 121.

Also, the instrument member 110 may be a chassis or a heat dissipation plate.

Also, the substrate 120 may be a circuit driving board.

Meanwhile, as illustrated in FIG. 1, a plurality of the magnetic bodies 121 may be formed to be spaced apart from one another on the same plane.

Also, if the plurality of magnetic bodies 121 include N-pole and S-pole magnetic bodies as illustrated in FIG. 1, the N-pole magnetic bodies and the S-pole magnetic bodies may be alternately arranged. This is to further improve a bonding force between the elements of the light emitting diode package module 100.

### Light Emitting Diode Package Module

### Second Embodiment

FIG. 2 is a detailed view of a structure of a light emitting diode package module 100 according to a second embodiment of the present invention.

Here, a description of elements which are the same as those of the light emitting diode package module 100 according to the first embodiment will be omitted, and the description will focus on the differences from the first embodiment only.

As illustrated in FIG. 2, the light emitting diode package module 100 may include a substrate 120, a light emitting diode package 130 formed on the substrate 120, an instrument member 110 formed below the substrate 120, and magnetic bodies 111, 121, and 132 formed on the substrate 120, the light emitting diode package 130, or the instrument member 110.

As illustrated in FIG. 2, when the magnetic body 132 is formed on a substrate surface of the light emitting diode package 130, the substrate 120 and the instrument member 110 each may further include a metal layer 122 that is formed on an upper surface or a lower surface of the substrate 120 and the instrument member 110 and is formed of a material that reacts with the magnetic body 132.

While a metal layer formed on the instrument member 110 is omitted in FIG. 2 for convenience of description, a metal layer may be formed on the upper surface or the lower surface of the instrument member 110.

Here, the substrate surface of the light emitting diode package is defined as a surface of the light emitting diode package 130 that contacts the substrate 120.

Also, if the magnetic body 132 is formed on the substrate surface of the light emitting diode package 130, the substrate 120 and the instrument member 110 may be each formed of a metal which reacts with the magnetic body 132.

For example, the substrate 120 and the instrument member 110 may be formed by using materials including iron or nickel which reacts with a magnetic body.

Accordingly, an additional metal layer is not necessary on the substrate 120 and the instrument member 110, but the current embodiment of the present invention is not limited thereto. For example, an additional metal layer may be formed on the substrate 120 and the instrument member 110 so as to further improve an attractive force between the substrate 120 and the instrument member 110 and the magnetic body 132.

Also, the instrument member 110 may be a chassis or a heat dissipation plate.

Also, the substrate 120 may be a circuit driving board.

Meanwhile, as illustrated in FIG. 2, a plurality of the magnetic bodies 132 may be formed to be spaced apart from one another on the same plane.

Also, if the plurality of magnetic bodies 132 include N-pole and S-pole magnetic bodies as illustrated in FIG. 2, the N-pole magnetic bodies and the S-pole magnetic bodies may be alternately arranged.

### Light Emitting Diode Package Module

### Third Embodiment

FIG. 3 is a detailed view of a structure of a light emitting diode package module 100 according to a third embodiment of the present invention.

Here, a description of elements that are the same as those of the light emitting diode package module 100 according to the first embodiment will be omitted, and the description will focus on the differences from the first embodiment only.

As illustrated in FIG. 3, the light emitting diode package module 100 may include a substrate 120, a light emitting diode package 130 formed on the substrate 120, an instrument member 110 formed below the substrate 120, and magnetic bodies 111, 121, and 132 formed on the substrate 120, the light emitting diode package 130, or the instrument member 110.

As illustrated in FIG. 3, when the magnetic body 111 is formed on a substrate surface of the instrument member 110, the substrate 120 and the light emitting diode package 130 each may further include metal layers 131 and 122 that are formed on an upper surface or a lower surface of the substrate 120 and the light emitting diode package 130 and formed of a material that reacts with the magnetic body 111.

Here, the substrate surface of the instrument member 110 is defined as a surface of the instrument member 110 that contacts the substrate 120.

Also, if the magnetic body 111 is formed in the substrate surface of the instrument member 110, the substrate 120 and the light emitting diode package 130 may be each formed of a metal which reacts with the magnetic body 111.

Accordingly, an additional metal layer is not necessary on the substrate 120 and the light emitting diode package 130, but the current embodiment of the present invention is not limited thereto. For example, additional metal layers 131 and 122 may be formed on the substrate 120 and the light emitting diode package 130 so as to further improve an attractive force between the substrate 120 and the light emitting diode package 130 and the magnetic body 111.

Also, the instrument member 110 may be a chassis or a heat dissipation plate.

Also, the substrate 120 may be a circuit driving board.

Meanwhile, as illustrated in FIG. 3, a plurality of the magnetic bodies 111 may be formed to be spaced apart from one another on the same plane.

Also, if the plurality of magnetic bodies 111 includes N-pole and S-pole magnetic bodies as illustrated in FIG. 3, the N-pole magnetic bodies and the S-pole magnetic bodies may be alternately arranged.

### Light Emitting Diode Package Module

### Fourth embodiment

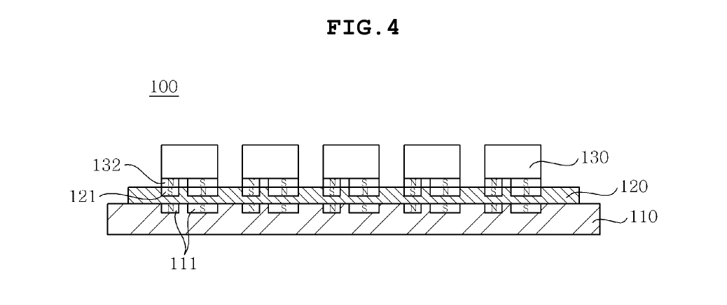

FIG. 4 is a detailed view of a structure of a light emitting diode package module 100 according to a fourth embodiment of the present invention.

Here, a description of elements that are the same as those of the light emitting diode package module 100 according to the first embodiment will be omitted, and the description will focus on the differences from the first embodiment only.

As illustrated in FIG. 4, the light emitting diode package module 100 may include a substrate 120, a light emitting diode package 130 formed on the substrate 120, an instrument member 110 formed below the substrate 120, and magnetic bodies 111, 121, and 132 formed on the substrate 120, the light emitting diode package 130, or the instrument member 110.

A plurality of magnetic bodies 111, 121, and 132 may be formed to be spaced apart from one another on the same plane of each of the substrate 120, the light emitting diode package 130, and the instrument member 110.

Also, if the plurality of magnetic bodies 111, 121, and 132 include N-pole and S-pole magnetic bodies, the N-pole magnetic bodies and the S-pole magnetic bodies may be alternately arranged on the same plane of each of the substrate 120, the light emitting diode package 130, and the instrument member 110.

In addition, if the plurality of magnetic bodies 111, 121, and 132 include N-pole and S-pole magnetic bodies, the N-pole magnetic bodies and the S-pole magnetic bodies may be alternately arranged on the regions each corresponding to the substrate 120, the light emitting diode package 130, and the instrument member 110.

For example, as illustrated in FIG. 4, among the magnetic bodies 132, 121, and 111, when an N pole magnetic body is arranged as a first magnetic body of the light emitting diode package 130, then an S-pole magnetic body is arranged as a first magnetic body on the substrate 120, while an N-pole magnetic body is arranged as a first magnetic body on the instrument member 110.

The above-described arrangement is conducted in order to further improve attractive forces between the magnetic bodies 111, 121, and 132.

Magnetic intensities of the magnetic bodies 111, 121, and 132 illustrated in FIGS. 1 through 4 may be adjusted by an operator to be either strong or weak.

According to the prior art, surface mounting for a light emitting diode package module is performed by using a solder (or a conductive paste) in a surface mounting technology (SMT) process, and a screw is coupled or is attached by using an adhesive in an operation of attaching an instrument member (chassis or heat dissipation plate). Accordingly, discoloration of surfaces is caused during a reflow operation and it is difficult to reprocess when characteristics of a material that is vulnerable to heat vary or a defect is generated in a predetermined element.

However, according to the embodiments of the present invention, magnetic bodies are applied to a light emitting diode package module, and elements of the light emitting diode package module is assembled by using the magnetic bodies, and thus the light emitting diode package modules may be easily assembled together without an additional adhering operation such as an adhesive or a screw or the like.

In addition, if a defect is generated in a particular element of the light emitting diode package module, the element may be easily replaced because elements of the light emitting diode package module according to the embodiments of the present invention may be easily separated from one another since use of an additional adhesive or a screw is omitted.

According to the light emitting diode package module of the embodiments of the present invention, a magnetic body is used to assemble elements of the light emitting diode package module, and thus, operations such as an additional soldering operation may be omitted. Thus, the manufacturing process of the light emitting diode package module may be simplified.

Also, according to the light emitting diode package module of the embodiments of the present invention, the elements of the light emitting package module are assembled by using a magnetic body. Accordingly, the elements included in the light emitting diode package module may be easily separated from one another, and thus if a defect occurs in a predetermined portion, the corresponding part may be easily replaced.

Although the preferred embodiments of the present invention have been disclosed for illustrative purposes, they are for specifically explaining the present invention. Therefore, a light emitting diode package module according to the preferred embodiments of the present invention is not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention can be defined by the accompanying claims.

What is claimed is:

1. A light emitting diode package module, comprising:
a substrate;
a light emitting diode package formed on the substrate;
an instrument member formed below the substrate; and
a magnetic body formed on the substrate, the light emitting diode package, or the instrument member.

2. The light emitting diode package module as set forth in claim 1, wherein when the magnetic body is formed on the substrate, the light emitting diode package and the instrument member each further include a metal layer that is formed on an upper surface or a lower surface of the light emitting diode package and the instrument member and is formed of a material that reacts with the magnetic body.

3. The light emitting diode package module as set forth in claim 1, wherein when the magnetic body is formed on the substrate, the light emitting diode package and the instrument member are each formed of a metal which reacts with the magnetic body.

4. The light emitting diode package module as set forth in claim 1, wherein when the magnetic body is formed on a substrate surface of the light emitting diode package, the substrate and the instrument member each further include a metal layer that is formed on an upper surface or a lower surface of the substrate and the instrument member and is formed of a material that reacts with the magnetic body.

5. The light emitting diode package module as set forth in claim 1, wherein when the magnetic body is formed on a substrate surface of the light emitting diode package, the substrate and the instrument member are each formed of a metal which reacts with the magnetic body.

6. The light emitting diode package module as set forth in claim 1, wherein when the magnetic body is formed on a substrate surface of the instrument member, the substrate and the light emitting diode package each further include a metal layer that is formed on an upper surface or a lower surface of the substrate and the light emitting diode package and is formed of a material that reacts with the magnetic body.

7. The light emitting diode package module as set forth in claim 1, wherein when the magnetic body is formed on a substrate surface of the instrument member, the substrate and the light emitting diode package are each formed of a metal which reacts with the magnetic body.

8. The light emitting diode package module as set forth in claim 1, wherein the instrument member is a chassis or a heat dissipation plate.

9. The light emitting diode package module as set forth in claim 1, wherein the substrate is a circuit driving board.

10. The light emitting diode package module as set forth in claim 1, wherein a plurality of the magnetic bodies are formed to be spaced apart from one another on the same plane.

11. The light emitting diode package module as set forth in claim 10, wherein when the plurality of magnetic bodies include N-pole magnetic bodies and S-pole magnetic bodies, the N-pole magnetic bodies and the S-pole magnetic bodies are alternately arranged.

12. A light emitting diode package module, comprising:
a substrate;
a light emitting diode package formed on the substrate;
an instrument member formed below the substrate; and
a magnetic body formed on each of the substrate, the light emitting diode package, and the instrument member.

13. The light emitting diode package module as set forth in claim 12, wherein a plurality of magnetic bodies are formed to be spaced apart from one another on the same plane of each of the substrate, the light emitting diode package, and the instrument member.

14. The light emitting diode package module as set forth in claim 13, wherein when the plurality of magnetic bodies include N-pole magnetic bodies and S-pole magnetic bodies, the N-pole magnetic bodies and the S-pole magnetic bodies are alternately arranged on the same plane of each of the substrate, the light emitting diode package, and the instrument member.

15. The light emitting diode package module as set forth in claim 13, wherein when the plurality of magnetic bodies include N-pole magnetic bodies and S-pole magnetic bodies, the N-pole magnetic bodies and the S-pole magnetic bodies are alternately arranged on the regions each corresponding to the substrate, the light emitting diode package, and the instrument member.
